(19) United States
(12) Patent Application Publication
(10) Pub. No.: US 2025/0189593 A1
(43) Pub. Date: Jun. 12, 2025

(54) BATTERY SYSTEM CONTROL BASED ON STATE SPACE AGING MODELING

(71) Applicant: Cuberg, Inc., San Leandro, CA (US)

(72) Inventor: Maxwell Dylla, Oakland, CA (US)

(73) Assignee: Cuberg, Inc., San Leandro, CA (US)

(21) Appl. No.: 18/535,970

(22) Filed: Dec. 11, 2023

(51) Int. Cl. G01R 31/392; G01R 31/367; G01R 31/3842

(52) U.S. Cl. CPC G01R 31/392; G01R 31/367; G01R 31/3842

(57) ABSTRACT

A request may be received to determine a control profile for a device to perform a course of action. The request may include input values characterizing a state of a battery system included in the device and/or the course of action. Fixed parameter values may be determined based on the input values. Prospective control profiles may be determined for the device. The prospective control profiles may share the fixed parameter values and may each have a respective set of variable parameter values that vary across the plurality of prospective control profiles. A battery system state space prediction model may be applied to determine corresponding battery system state space output values. A selected prospective control profile may be determined, and an instruction to execute the selected prospective control profile may be transmitted to a device controller.

### FIELD OF TECHNOLOGY

This patent application relates generally to battery technologies, and more specifically to battery management systems.

### BACKGROUND

Predicting battery system data values is important for a variety of applications. In the absence of accurate prediction, a device that depends on a battery system for power may suffer unexpected power loss. Unanticipated power loss can lead to negative outcomes such as failure to complete a task, damage to the device itself, damage to other objects, or injury to people. Battery system state prediction is thus increasingly important as an ever-growing number of devices transition to a battery-powered configuration.

However, battery systems exhibit complex behavior that is difficult to predict. Different combinations of battery histories, current battery values, operating conditions, control protocols, and other such characteristics mean that predicting a future state, such as an amount of charge remaining at a particular point in time in the future, is a difficult task. Conventional techniques for battery state prediction suffer from inaccuracy. Moreover, many conventional techniques are tailored to particular types of batteries, devices, operating conditions, and the like.

The way a battery is used influences how it degrades, which can result in different lifetimes for the battery under different use patterns. For example, a battery subject to faster charging conditions may degrade faster in the sense that it will last fewer cycles before failing. Accordingly, improved systems and methods for battery system state prediction are needed.

### SUMMARY

According to various embodiments, techniques and mechanisms described herein include methods, systems, and non-transitory computer readable media having instructions stored thereon for battery system state space prediction and control profile determination. In some embodiments, a request may be received to determine a control profile for a device to perform a course of action. The request may include a first one or more input values characterizing a state of a battery system included in the device. The request may also include a second one or more input values characterizing the course of action. One or more fixed parameter values may be determined based on the first one or more input values and/or the second one or more input values. A plurality of prospective control profiles may be determined for the device. The plurality of prospective control profiles may share the one or more fixed parameter values. The plurality of prospective control profiles may each have a respective set of variable parameter values that vary across the plurality of prospective control profiles. A battery system state space prediction model may be applied to the plurality of prospective control profiles via a processor to determine a plurality of corresponding battery system state space output values. A selected prospective control profile may be determined from the plurality of prospective control profiles based at least in part on the plurality of prospective control profiles. An instruction may be transmitted to a device controller to execute the selected prospective control profile.

In some embodiments, the device may be an electric vehicle powered by the battery system, and the course of action may include moving from a source location to a destination location. Alternatively, or additionally, the one or more fixed parameter values may identify the source location and the destination location. Alternatively, or additionally, the variable parameter values may identify different speeds at which the electric vehicle may travel. Alternatively, or additionally, the variable parameter values may identify cargo amounts transported by the electric vehicle.

In some embodiments, the one or more fixed parameter values may identify a state of health for the battery system prior to performing the course of action. The plurality of corresponding battery system state space output values may identify a plurality of predicted changes in the state of health for the battery system after performing the course of action in accordance with the plurality of prospective control profiles.

In some embodiments, the plurality of corresponding battery system state space output values may identify a plurality of predicted states of health for the battery system after performing the course of action in accordance with the plurality of prospective control profiles.

In some embodiments, the communication interface may be located at a cloud computing system. The plurality of prospective control profiles may correspond to different pricing levels for use of the battery system.

In some implementations, a designated prospective control profile of the plurality of prospective control profiles may include a designated current profile defining an amount of current over a designated period of time or a designated power profile defining an amount of power.

In some embodiments, the first one or more input values encode information may correspond to one or more sensors associated with the battery system.

According to various embodiments, the battery system state space prediction model may be a temporal convolutional neural network, a random forest model, or a multilayer perceptron model.

In some embodiments, the plurality of corresponding battery system state space output values may include a hidden value not observable via one or more sensors associated with the battery system. The hidden value may be one or more of a hidden resistance value, a hidden capacitance value, a hidden electrolyte connectivity value, and a hidden a cathode conductivity value.

### BRIEF DESCRIPTION OF THE DRAWINGS

The included drawings are for illustrative purposes and serve only to provide examples of possible structures and operations for the disclosed inventive systems, apparatus, methods, and computer program products for battery management. These drawings in no way limit any changes in form and detail that may be made by one skilled in the art without departing from the spirit and scope of the disclosed implementations.

FIG. 1 illustrates an overview method for a battery system state space prediction model, performed in accordance with one or more embodiments.

FIG. 2 illustrates a flow diagram of a process flow performed in accordance with one or more embodiments.

FIG. 3 is a block diagram of battery pack that may be used in conjunction with techniques and mechanisms described herein.

FIG. 4 illustrates one example of a computing system configured in accordance with one or more embodiments.

FIG. 5A illustrates a conceptual diagram of a prediction framework for a battery system in an inference phase.

FIG. 5B illustrates a conceptual diagram of a prediction framework for a battery system in a training phase.

FIG. 6 illustrates a diagram of a battery value temporal convolutional neural network, configured in accordance with one or more embodiments.

FIG. 7 illustrates a method for training a battery system state space prediction model, performed in accordance with one or more embodiments.

FIG. 8A, FIG. 8B, FIG. 8C, FIG. 8D, FIG. 9A, FIG. 9B, FIG. 9C, and FIG. 9D illustrate examples of plots generated in accordance with one or more embodiments.

FIG. 10 illustrates a method of controlling a device, performed in accordance with one or more embodiments.

FIG. 11 illustrates a method of controlling a fleet of devices, performed in accordance with one or more embodiments.

### DETAILED DESCRIPTION

Techniques and mechanisms described herein relate to battery system state space prediction models, which represent a physical battery system in a way that establishes relationships between input variables and state variables associated with the battery system. Input variables may include values that represent the external conditions applied to the battery. Examples of input variables may include, but are not limited to, the charge rate, the ambient temperature, the depth of discharge, and/or other such conditions. State variables may include various characteristics associated with the battery system itself, which may provide an indication as to the health of the battery system. Examples of state variables may include, but are not limited to: internal resistance, capacity retention, and other such values.

Many conventional techniques for predicting battery system aging ignore the current state of the battery system. Because such approaches consider relationships between applied conditions and battery state, they poorly predict battery system aging over time. Further, many conventional techniques for predicting battery system state are poorly adapted to battery systems that experience a wide range of battery states, such as batteries operating in mobile vehicles.

In contrast to conventional techniques, various embodiments of techniques and mechanisms described herein provide for a battery system state space prediction model may be trained over a variety of aging conditions for a battery design. For instance, the battery system state space prediction model may be trained to predict a future state of a battery system given information about a current state of the battery system, one or more past states of the battery system, and/or one or more external conditions applied. The battery system state space prediction model may be updated based on usage data collected from a field environment.

According to various embodiments, battery system state space prediction models may be used for a variety of applications. For instance, a usage profile defines a segment in time of defined usage conditions applied to a battery at a given initial state. Different usage profiles may affect the battery system in different ways. The impact of different usage profiles on the battery system may be predicted in advance via the trained battery system state space prediction model. Such predictions may be used to guide selection or pricing of prospective battery profiles for application to a battery system. In this way, a battery system may be used more efficiently, for instance to support an extended lifetime for the battery system. Thus, embodiments of techniques and mechanisms described herein may provide for improved performance and greater efficiency of a battery system by predicting in advance how a course of action will affect a future state of the battery system.

According to various embodiments, techniques and mechanisms described herein may employ any of a wide variety of prediction models. Such prediction models may include, but are not limited to, random forest prediction models, multilayer perceptron prediction models, and time-series prediction models.

In some embodiments, future system values may be predicted based on current and past system values using a battery value temporal convolutional neural network. A battery value temporal convolutional neural network may include an input layer of neurons corresponding to battery system data over a period of time, and an output layer of neurons corresponding to battery system predictions at particular points in time. One or more hidden layers of neurons between the input layer and the output layer may provide for time dilation, allowing a prediction for a particular point in time to be made based on input from a window of time into the past coupled with a candidate control protocol defining a current profile and/or power profile applied to the battery system.

As used herein, the term “control protocol” refers to a pattern of control for a device that includes a battery system. For example, a control protocol may define a current profile specifying an amount of current applied over time. As another example, a control protocol may define a power profile specifying an amount of power extracted from a battery system over time. As yet another example, a control protocol may define a set of

Some conventional techniques provide for predicting some future aspects of a battery system. However, conventional techniques typically involve training separate prediction models for separate aspects of a battery system, such as separate models for parameter identification, state estimation, and response. In contrast, various embodiments of techniques and mechanisms described herein provide for combining parameter identification, state estimation, and the prediction of future battery system responses into a single learned task inside a neural network provide for holistic system inference.

Conventional approaches for predicting future aspects of a battery system suffer from a lack of accuracy, speed, and reliability. In contrast, various embodiments of techniques and mechanisms described herein provide for improved accuracy, speed, and/or reliability.

According to various embodiments, techniques and mechanisms described herein are applicable in a wide range of contexts. For example, a device may be tasked with performing an action but may have several ways in which the action could be performed. In such a situation, candidate control protocols may be created that correspond with the various ways in which the action could be performed. A battery system state space prediction model may then be applied to these candidate control protocols to select a course of action consistent with one or more criteria, such as a future state of the battery system. As another example, a fleet management system may be managing a fleet of devices that vary in characteristics such as a condition, state of charge, and location. In order to accomplish a set of tasks, the fleet management system may need to determine a set of devices and/or control protocols to achieve a particular goal, such as increased battery system lifespan across the fleet of devices.

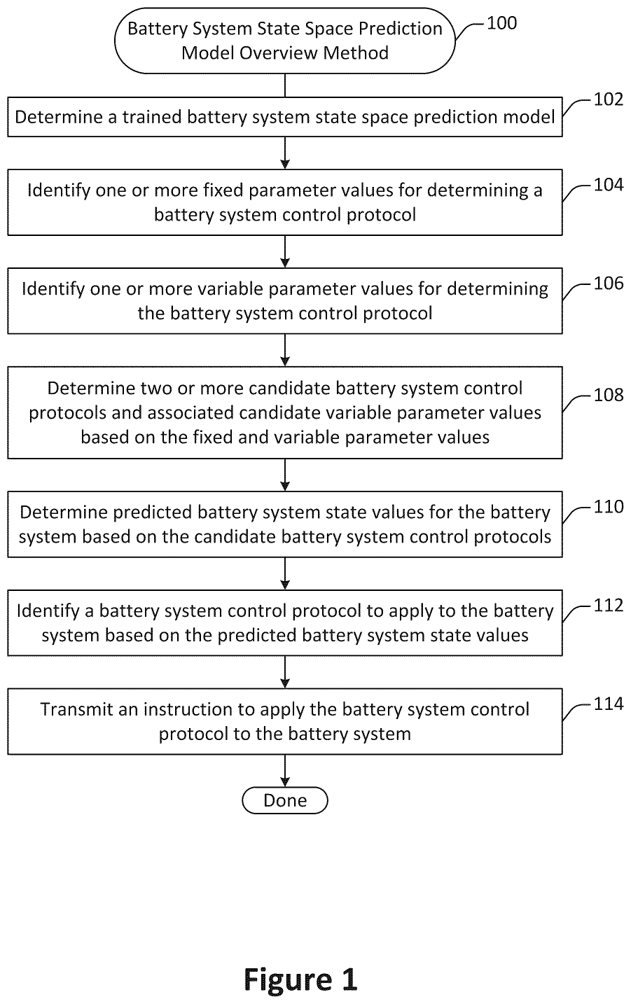

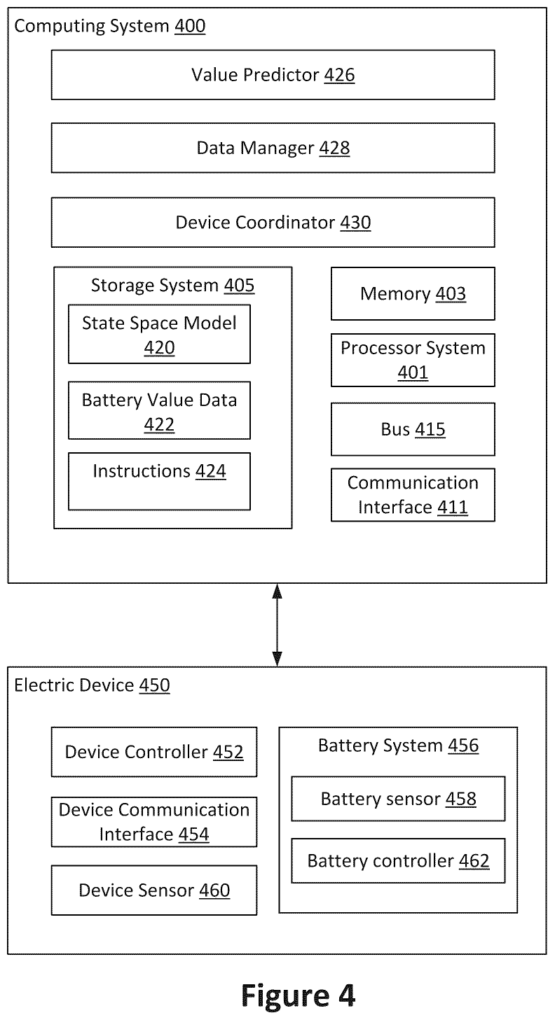

FIG. 1 illustrates an overview method 100 for a battery system state space prediction model, performed in accordance with one or more embodiments. According to various embodiments, the method 100 may be performed by any of a variety of suitable computing devices, such as the system 400 shown in FIG. 4. In some configurations, different elements of the method 100 may be performed by different computing devices.

A trained battery system state space prediction model is determined at 102. In some embodiments, the battery system state space prediction model may be trained to predict a future state of the battery system based on one or more input parameters. The future state of the battery system may indicate the health of the battery system. For instance, the future state of the battery system may provide an indication as to the remaining useful life of the battery system.

In some embodiments, the one or more input parameters may include input to the battery system itself (e.g., voltage). Alternatively, or additionally, the one or more input parameters may include parameters associated with the device in which the battery system is situated. For instance, in an aeronautics context, the input parameters may include a distance to be traveled by an airplane, an amount of cargo carried by the airplane, a time spent taxiing for the airplane, an amount of time needed to traverse the distance, and the like.

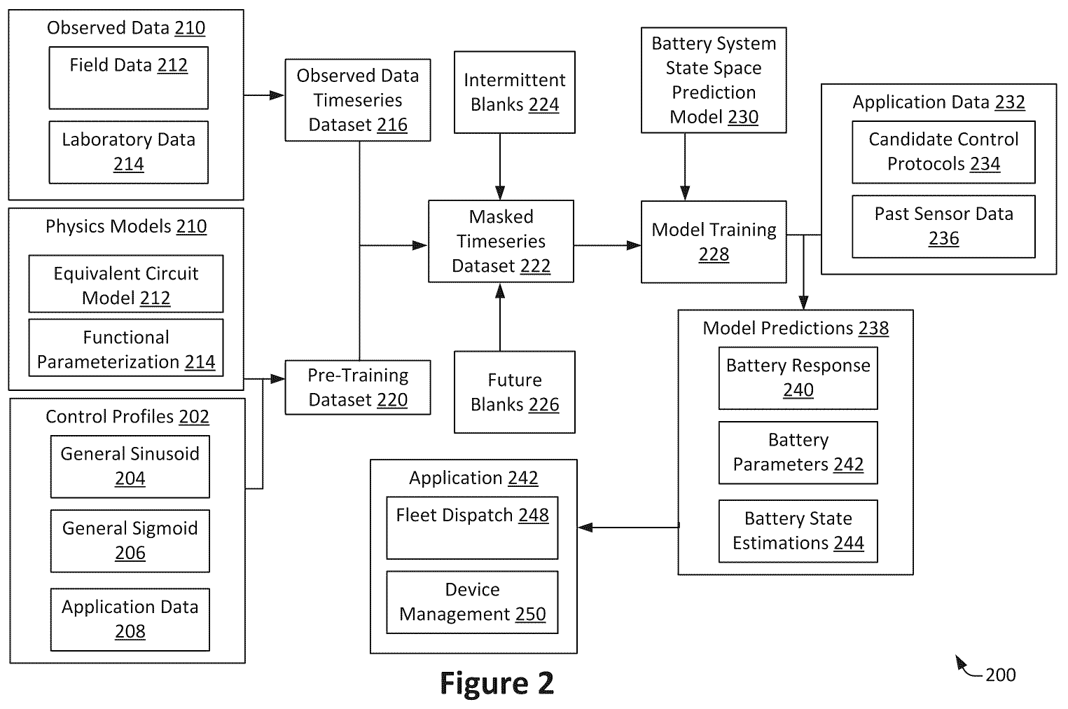

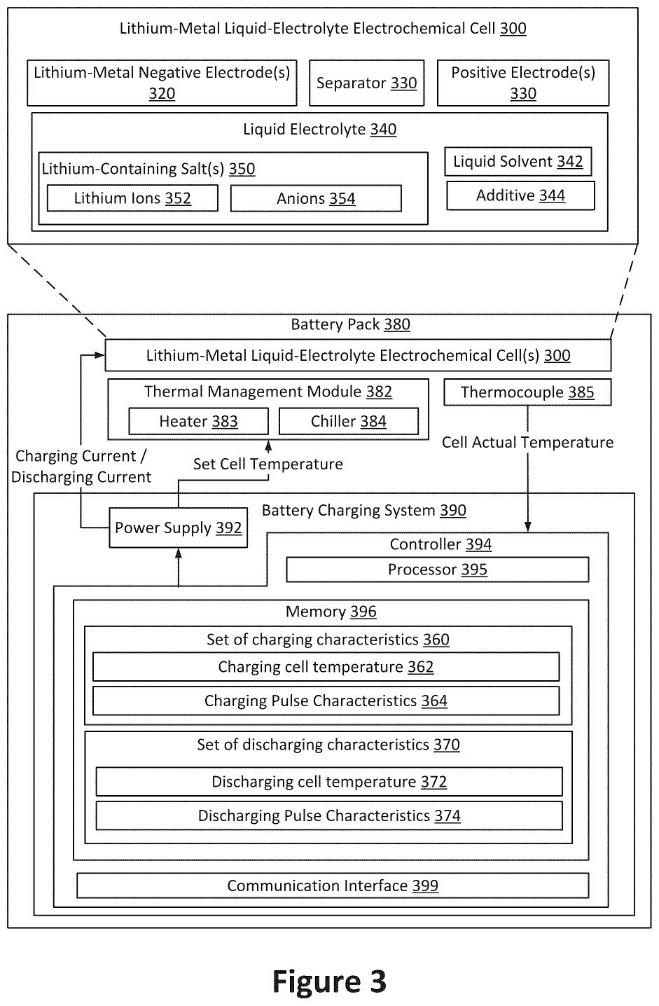

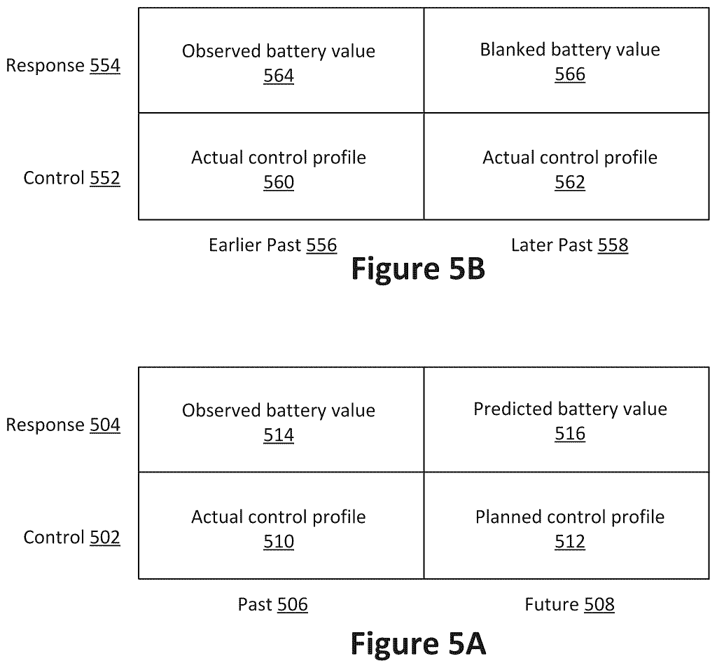

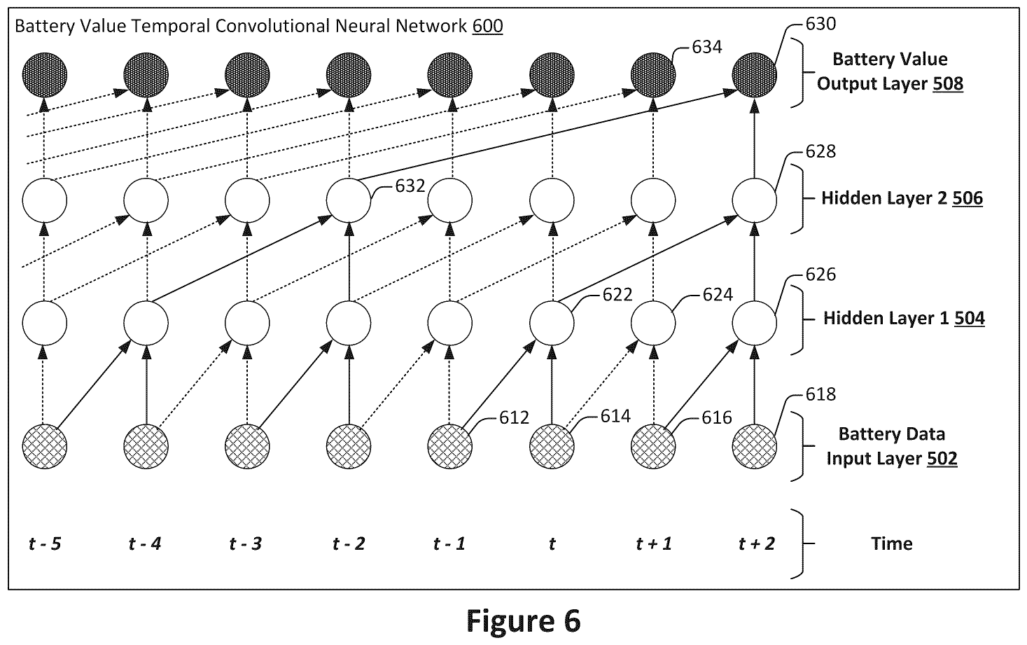

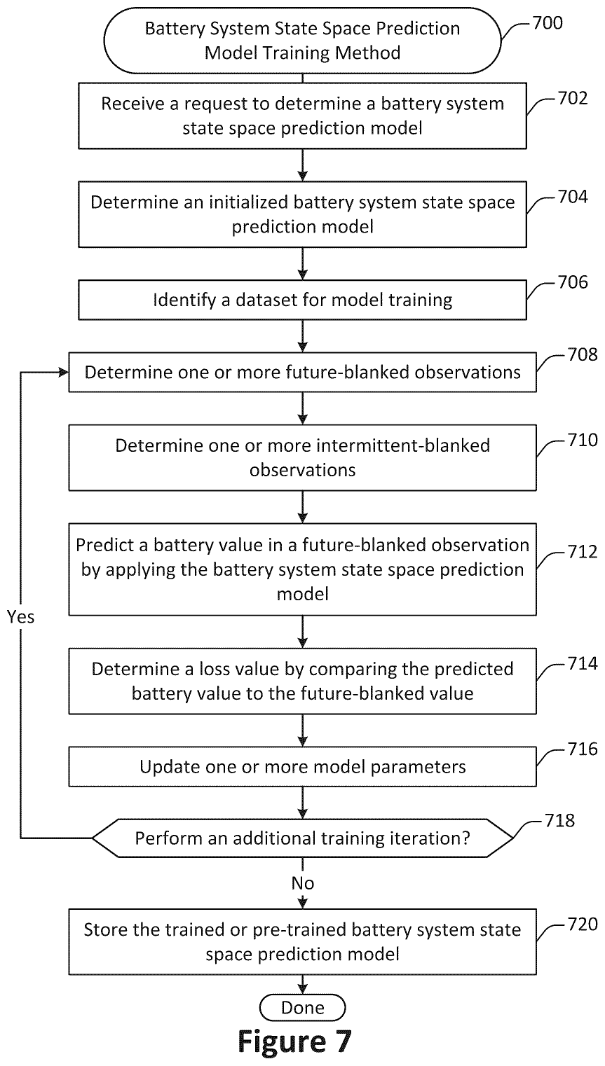

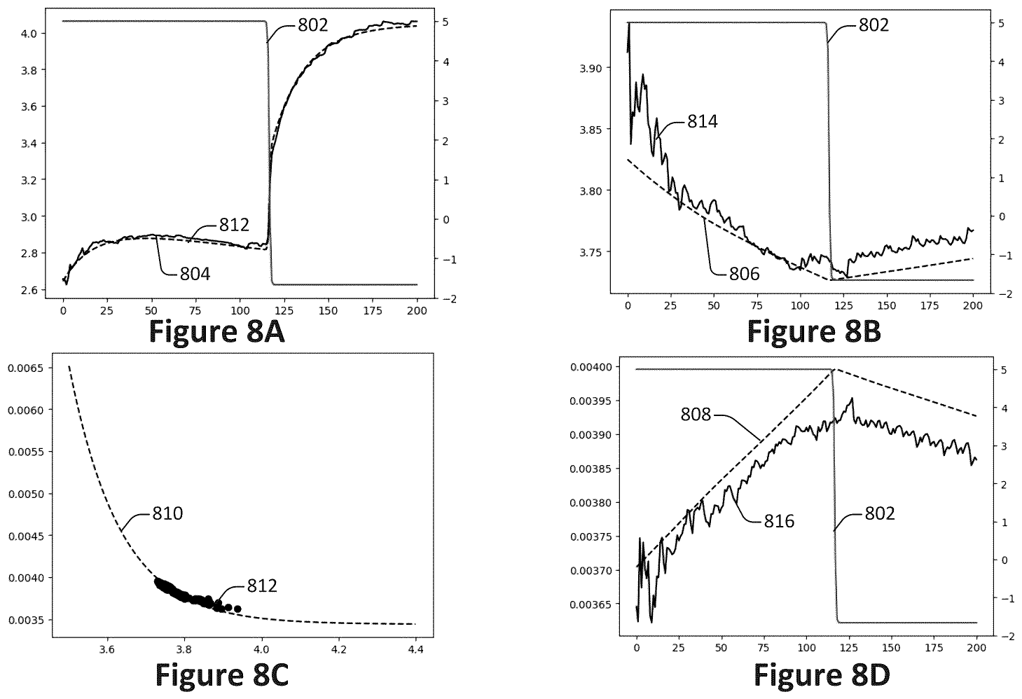

Additional details regarding configurations of battery system state space prediction models as well as battery systems and the devices in which they may be situated are discussed with respect to FIG. 2, FIG. 3, FIG. 4, FIG. 5, and FIG. 6. Additional details regarding the training of a battery system state space prediction model are discussed with respect to the method 700 shown in FIG. 7.

One or more fixed parameter values for determining a battery system control protocol are identified at 104. In some embodiments, the fixed parameter values may include values that may be provided as inputs to the battery system state space prediction model that may not be changed if a task is to be accomplished. For example, in the vehicular space, the fixed parameter values may identify a current location and a destination of an electric vehicle.

One or more variable parameter values for determining the battery system control protocol are identified at 106. In some embodiments, the variable parameter values may include values that may be provided as inputs to the battery system state space prediction model that may be altered while still accomplishing the text. For example, the vehicular space, the fixed parameter values may identify information related to different routes for moving between a current location and a destination, different weight values for cargo that the vehicle may carry, different speeds at which the distance may be traversed, and the like.

One or more candidate battery system control protocols and associated variable parameter values are determined 108. According to various embodiments, the one or more candidate battery system control protocols may be determined by varying the variable parameter values, for instance within acceptable ranges. The candidate battery system control protocols may then be determined by combining the variable parameter values with the fixed parameter values.

Predicted battery system state values for the battery system are determined at 110 based on the candidate battery system control protocols. In some embodiments, the predicted battery system state values may be determined by applying the trained battery system state space prediction model to the candidate battery system control values. The predicted battery system state space values may indicate, for example, a predicted health of the battery system.

A battery system control protocol to apply to the battery system is determined at 112 based at least in part on the predicted battery system state values. In some embodiments, the battery system control protocol to apply may be determined based at least in part based on comparing the predicted battery system state values determined at 110. For instance, some candidate battery system control protocols may result in better predicted future battery state values than others.

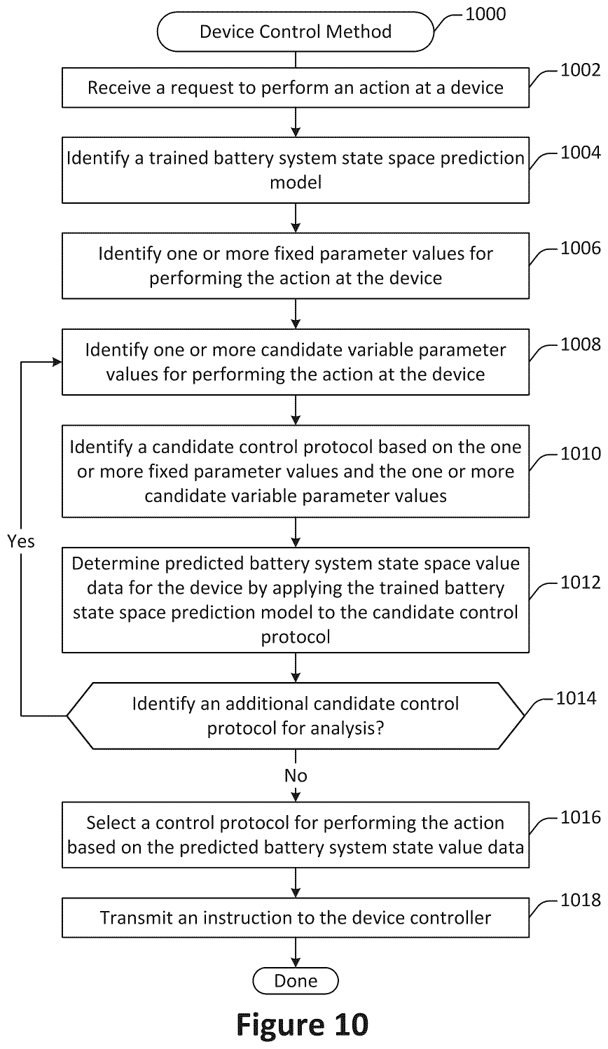

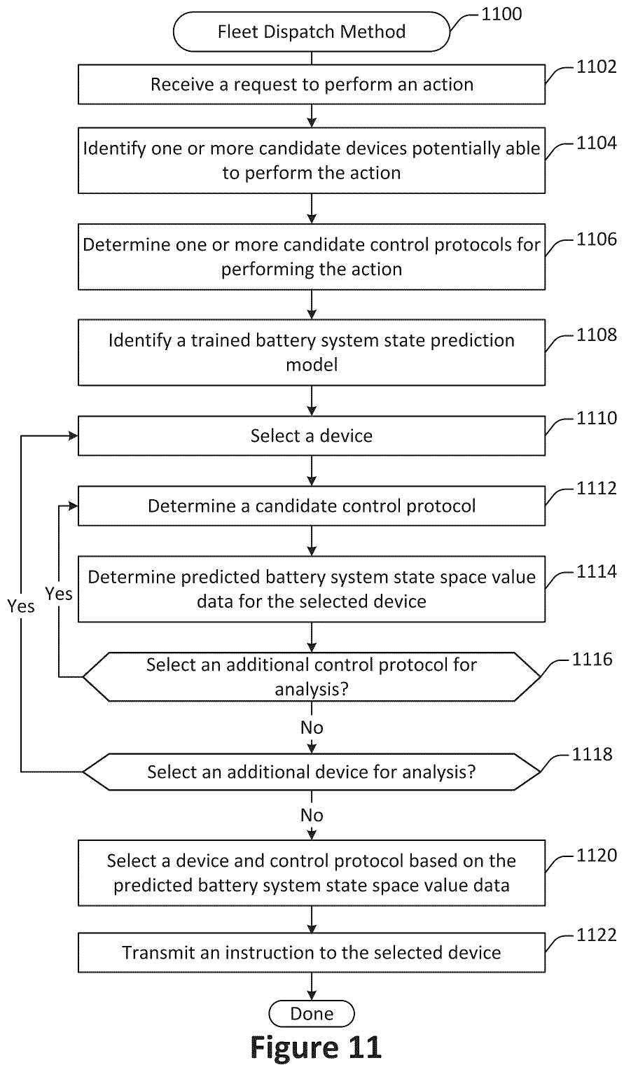

An instruction to apply the battery system control protocol to the battery system is transmitted at 114. In some embodiments, the instruction may be transmitted by and/or to the device in which the battery system is situated, such as an electric vehicle. Additional details regarding the determination and application of candidate battery system control protocols, the determination of predicted battery system state values are discussed with respect to the methods 1000 and 1100 shown in FIG. 10 and FIG. 11.

FIG. 2 illustrates a flow diagram of a process flow 200 performed in accordance with one or more embodiments. At a high level, the process flow 200 illustrates operations performed in the training and application of a battery value temporal convolutional neural network.

According to various embodiments, a battery value temporal convolutional neural network may be trained based on a pre-training dataset 220 and/or an observed data dataset 216. For instance, a model may be initially trained on a pre-training dataset 220 and then updated based on an observed data dataset 216 as additional data becomes available.

In some embodiments, an observed data dataset 216 may be determined based on observed data 210. The observed data 210 may include laboratory data 214 collected from a laboratory environment, for instance by subjecting a battery system to various conditions and control protocols and observing state data for the battery system collected by one or more sensors. Alternatively, or additionally, the observed data 210 may include field data 212 collected from battery systems deployed to devices in a field environment.

In some embodiments, a pre-training dataset 220 may be determined based on one or more control protocols 202 applied to one or more physics models 210. A control protocol represents a set of conditions for charging and/or discharging the battery system. For instance, a control protocol may specify a current protocol and/or power protocol for the battery system over a period of time.

In some implementations, a control protocol may be a simulated protocol determined based on a mathematical functional form. Examples of such control protocols include general sinusoid control protocols 204 and general sigmoid control protocols 206, although other functional forms may also be used. Alternatively, or additionally, a control protocol may be determined based on application data 208 that reflects real-world conditions of battery systems deployed to a field environment.

In some embodiments, predicted battery system values may be determined for a battery system by applying one or more physics models 210 to a control protocol. A physics model may include an equivalent circuit model 212 that captures theoretical physical characteristics of a battery system, initialized using a functional parameterization 214 that specifies one or more characteristics of the operation of the battery system.

According to various embodiments, a masked dataset 222 (also referred to herein as a blanked dataset) may be determined based on one or more observed data datasets and/or one or more pre-training datasets 220. Determining a masked dataset 222 may involve masking, or blanking, one or more values in the input dataset. For example, a future value such as a battery voltage may be masked for training purposes. The model may then be tasked with predicting the masked value, and the model's weights updated based on a loss value determined by comparing the predicted value with the actual value that was masked. As another example, one or more intermittent blanks may be introduced into a dataset to reflect the fact that real-world data for battery systems often includes missing values.

At 228, a battery system state space prediction model 230 is trained using the masked dataset 222. In some embodiments, training the model may involve training an entirely new model. Alternatively, an existing model may be updated, for instance to reflect newly received training data.

The trained model is used in conjunction with application data 232 to produce one or more model predictions at 238. The application data 232 may include one or more candidate control protocols 234 for which predicted battery value information is desired. The application data 232 may also include past sensor data 236 for use in predicting the future battery value information.

According to various embodiments, the model predictions 238 may include any or all of a variety of types of information, collectively referred to as “battery data values”. The battery data values included in the model predictions 238 may include one or more battery response values 240, one or more battery parameter values 242, and/or one or more battery state values 244. For example, battery response values 240 may include data such as terminal voltage or battery temperature. As another example, battery parameter values 242 may include underlying parameters of a physics model such as resistance values, capacitance values, or open circuit voltage. Parameter values may include hidden battery parameters that are not directly observable. As yet another example, battery state values 244 may include information such as state of charge or state of health.

Model predictions 238 may be used in any of a variety of applications 242. For example, model predictions may be employed to select a device and/or control protocol for performing an action in a fleet dispatch context 248. As another example, model predictions may be employed to determine a particular course of action in a device management context 250.

### Examples of Battery Systems

FIG. 3 is a block diagram of battery pack 380 that may be used in conjunction with techniques and mechanisms described herein. However, techniques and mechanisms described herein are applicable to a wide range of battery systems, and are not limited to the battery pack shown in FIG. 3.

The battery pack 380 comprises a lithium-metal liquid-electrolyte electrochemical cell 300, illustrating various additional components of battery pack 380, in accordance with some examples. Lithium-metal liquid-electrolyte electrochemical cell 300 comprises lithium-metal negative electrode 320, positive electrode 330, and separator 310, which is disposed and provides electronic isolation between lithium-metal negative electrode 320 and positive electrode 330. Lithium-metal liquid-electrolyte electrochemical cell 300 also comprises liquid electrolyte 340 which provides ionic transfer between lithium-metal negative electrode 320 and positive electrode 330. For example, liquid electrolyte 340 soaks separator 310 or, more specifically, the pores of separator 310.

Some examples of liquid electrolyte 340 include, but are not limited to, a mixture of one or more lithium-containing salts 350 and one or more liquid solvents 342. Some examples of lithium-containing salts 350 include, but are not limited to, lithium bis(fluorosulfonyl)imide (LiFSI), lithium bis(trifluoromethylsulfonyl)amide (LiTFSI), lithium tetrafluoroborate (LiBF₄), lithium hexafluorophosphate (LiPF), lithium bis(oxalato)borate (LiBOB), lithium difluoro(oxalato)borate (LiDFOB), lithium trifluoromethanesulfonate (LiTf), lithium nitrate (LiNO₃), and various combinations thereof. In some examples, lithium-containing salts 350 are LiFSI or LiTFSI, e.g., preferably LiFSI. Lithium-containing salts 350 are configured to dissociate into lithium ions 352 and anions 354. Some examples of liquid solvents 342 but are not limited to, one or more cyclic ethers (e.g., 3,3-dioxane (DOL), 3,4-dioxane (DX), tetrahydrofuran (THF)), one or more linear ethers (e.g., dimethoxyethane (DME), Bis(2-methoxyethyl) ether (G2), triethylene glycol dimethyl ether (G3), or tetraethylene glycol dimethyl ether (G4), Bis(2,2,2-trifluoroethyl)ether (BTFE); ethylal; 3,1,2,2-tetrafluoroethyl 2,2,3,3-tetrafluoropropyl ether (TFPE)), and combination thereof.

Liquid electrolyte 340 can comprises various additives 344, e.g., metal salts (e.g., having bis(trifluoromethanesulfonyl)imide (TFSI), bis(fluorosulfonyl)imide (FSI), hexafluorophosphate (PF₆), tetrafluoroborate (BF₄), and/or bis(oxalate)borate (BOB) anions), ionic liquids (eg., propyl-methyl-pyrrolidinium-FSI/TFSI; butyl-methyl-pyrrolidinium-FSI/TFSI; octyl-methyl-pyrrolidinium-FSI/TFSI, and any combination thereof), and the like.

In some examples, liquid electrolyte 340 can have a viscosity of at least 35 cP or, more specifically, at least 25 cP, at least 50 cP, or even at least 300 cP at room temperature. High viscosity can be driven by specific components needed in liquid electrolyte 340 to enable the functioning of liquid electrolyte 340 in lithium-metal liquid-electrolyte electrochemical cell 300.

Positive electrode 330 can include a current collector (e.g., an aluminum foil) and an active material layer comprising an active material (e.g., in a form of particles) and a binder (e.g., a polymer binder). Some examples of positive active materials include, but are not limited to, lithium nickel manganese cobalt (NMC) oxides, lithium iron phosphate, and the like. Some examples of suitable binders include, but are not limited to, polymer binders (e.g., polyvinylidene-fluoride (PVDF), styrene butadiene rubber (SBR), and carboxyl methyl cellulose (CMC)). In some examples, positive electrode 330 comprises a conductive additive (e.g., carbon black/paracrystalline carbon).

Negative electrode 330 can also include a current collector on which a lithium metal layer is deposited when lithium-metal electrochemical cell 310 is charged. Some examples of suitable current collectors include, but are not limited to, lithium (remaining after full discharged), copper, nickel, aluminum, stainless steel, a metalized polymer substrate (e.g., metalized with copper), and a carbon-coated metal substrate. The purpose of using a negative electrode with a lithium-metal layer deposited on a current collector (in lithium-metal electrochemical cells) is to reduce the size of the negative electrode (e.g., in comparison to lithium-ion cells). For example, the thickness of the lithium-metal layer can be less than 20 micrometers. Furthermore, the addition of a current collector also helps to keep the thickness of the lithium-metal layer small. For example, the thicknesses of less than 20 micrometers are difficult to achieve with a freestanding lithium foil. As such, lithium-metal cells with negative electrodes formed by freestanding lithium foils/layers require substantially more lithium than lithium-metal cells with negative electrodes formed by a combination of a current collector and a lithium-metal layer (to achieve the same cell capacity). Lower amounts of lithium are highly desirable from the safety perspective as less lithium ejecta (e.g., molten lithium ejecta) needs to be contained when the cell goes into a thermal runaway.

Positive electrode 330, lithium-metal negative electrode 320, separator 310, and liquid electrolyte 340 can be referred to as internal components of lithium-metal electrochemical cell 310. These internal components are sensitive to moisture and other ambient conditions and insulated from the environment by a cell enclosure, such as a metal (e.g., aluminum) case (e.g., for cylindrical or prismatic cells), a pouch laminate, an aluminum-coated polymer (e.g., polyamide, polyester, polyurethane, and polypropylene).

Battery pack 380 can include any number of lithium-metal liquid-electrolyte electrochemical cells 300, e.g., one, two, three, or more. Multiple lithium-metal liquid-electrolyte electrochemical cell 300 can be used with various types of in-series and/or parallel connections to boost the voltage and/or capacity of battery pack 300.

In some examples, battery pack 380 comprises thermocouple 385 to measure the temperature of lithium-metal liquid-electrolyte electrochemical cell 300. These temperature measurements can be used to trigger various charge and/or discharge operations as further described below. Furthermore, battery pack 380 can include thermal management module 382 for changing the temperature of lithium-metal liquid-electrolyte electrochemical cell 300. Thermal management module 382, when one is present, is thermally coupled to lithium-metal liquid-electrolyte electrochemical cell 300. Thermal management module 382 can include one or both heater 382 (e.g., a resistive heater) and chiller 384 (e.g., a liquid-cooled plate). Alternatively, lithium-metal liquid-electrolyte electrochemical cell 300 can be self-heated, e.g., using an AC excitation profile as further described below. The cooling of lithium-metal liquid-electrolyte electrochemical cell 300 can be provided by the environment.

In some examples, battery pack 380 comprises battery charging system 390 for controlling charge and discharging characteristics of lithium-metal liquid-electrolyte electrochemical cell 300. Battery charging system 390 can comprise power supply 392 configured to flow an electric current through lithium-metal liquid-electrolyte electrochemical cell 300 in accordance with the set of charging characteristics while charging lithium-metal liquid-electrolyte electrochemical cell 300 and in accordance with the set of discharging characteristics while discharging lithium-metal liquid-electrolyte electrochemical cell 300. Various examples of these characteristics are described below.

In some examples, battery charging system 390 comprises controller 394, communicatively coupled to power supply 392 and configured to control the operations of power supply 392, e.g., by providing the set of charging characteristics and the set of discharging characteristics. Controller 394 can also be communicatively coupled to thermocouple 385 and receive the temperature of lithium-metal liquid-electrolyte electrochemical cell 300, which is used for various control functions. Controller 394 can also be communicatively coupled to thermal management module 382 to control the operation of thermal management module 382 (e.g., heat or cool lithium-metal liquid-electrolyte electrochemical cell 300 to a set cell temperature).

In some examples, controller 394 comprises processor 395 and memory 396, e.g., storing set of charging characteristics 360 and set of discharging characteristics 370. For example, set of charging characteristics 360 comprises charging cell temperature 362, while set of discharging characteristics 370 comprises discharging cell temperature 372 such that charging cell temperature 362 is higher than discharging cell temperature 372. In the same or other examples, set of charging characteristics 360 comprises charging pulse characteristics 364, while set of discharging characteristics 370 comprises discharging pulse characteristics 364. For example, each pair of charging pulses is separated by a discharging pulse.

In some embodiments, the processor 395 is configured to predict a future battery value. For instance, as discussed throughout the application, the processor 395 may be configured to apply a battery state space network to one or more control protocols and/or sensor data received from one or more sensors at the battery pack 380 to predict one or more future values such as a future state of charge, temperature, voltage, current, or other such state. Battery state space networks are discussed in additional detail throughout the application.

The controller 394 also includes the communication interface 399. According to various embodiments, the communication interface 399 may communicate with one or more external devices, such as a remote computing system. The communication may take place via the internet or via another communication medium. The remote computing system may be configured to receiving battery measurement information, to process the battery measurement information in accordance with techniques and mechanisms described herein, and/or to transmit instructions to the battery pack 380 via the communication interface 399. For instance, the communication interface 399 may transmit to the remote computing system one or more measurements determined at the battery pack 380, and to receive an instruction determined based on a battery pack value predicted by the remote computing system.

### Examples of Control Systems and Devices

FIG. 4 illustrates one example of a computing system 400. According to various embodiments, a computing system 400 suitable for implementing embodiments described herein includes a processor system 401, a memory module 403, a storage system 405, a communication interface 411, and a bus 415 (e.g., a PCI bus or other interconnection fabric.) Computing system 400 may operate as variety of devices such as a battery management system, a fleet control system, a local device controller, a battery pack controller, a remote device controller, or any other device or service described herein. Although a particular configuration is described, a variety of alternative configurations are possible. The processor system 401 may include one or more physical processors and may perform operations such as those described herein. Instructions 424 for performing such operations may be embodied in the memory 403, on one or more non-transitory computer readable media, in the storage system 405, and/or on some other storage device. Various specially configured devices can also be used in place of or in addition to the processor system 401.

The storage system 405 includes a battery system state space prediction model 420, battery value data 422, and instructions 424. The computing system 400 includes a value predictor 426, a value data manager 428, and a device coordinator 430, one or more of which may operate on the basis of the instructions 424. According to various embodiments, the value predictor 426 may be configured to train the battery system state space prediction model 420 and/or to predict future battery values based on the battery system state space prediction model 420. Such predictions may be made based at least in part on the battery value data 422, which may store battery value data for one or more battery systems.

According to various embodiments, the battery data manager 428 may manage the battery value data 422. For example, the battery data manager 428 may receive sensor data, control data, or other battery value information and store battery value data 422 based on the received information. As another example, the battery value data manager 428 may determine actual and/or simulated training datasets based on physics model information. The training datasets may be stored as the storage system 405.

According to various embodiments, the device coordinator 430 may be responsible for coordinating communications with and instructions to and/or from one or more local and/or remote devices. For example, the device coordinator 430 may function as a battery management system. As another example, the device coordinator 430 may provide fleet control functionality for a fleet of devices. As another example, the device coordinator 430 may provide command and control functionality for any device that includes a battery system.

The communication interface 411 may be configured to send and receive data packets over a network, bus, or other communication link. For example, the communication interface 411 may be configured to communicate with a battery pack via the internet. As another example, the communication interface 411 may be configured to communicate with a battery cell via a bus. The communication interface 411 and associated components may include ports appropriate for communication with the appropriate media. They may also include an independent processor and/or volatile RAM. A computer system or computing device may include or communicate with a monitor, printer, or other suitable display for providing any of the results mentioned herein to a user.

The computing system 400 may be situated inside and/or in communication with an electric device 450. According to various embodiments, the electric device 450 may be any device that is powered by a battery system 456. For example, the electric device 450 may be an electric vehicle such as an electric airplane, drone, automobile, truck, motorcycle, robot, or the like. As another example, the electric device 450 may be a stationary device such as a power delivery system. The electric device 450 may include a device communication interface 454, which may be configured to communicate with the device coordinator 430 via the communication interface 411. The electric device 450 may also include a device controller 452.

In some embodiments, the device controller 452 may be configured to control the electric device 450, for instance by issuing instructions to the electric device 450. The device controller 452 may also be configured to collect information about the electric device via one or more sensors such as the device sensor 460.

In some embodiments, the battery system 456 may include one or more sensors such as the battery sensor 458. The battery sensor 458 may be configured to collect any of various types of information about the battery system 456, for instance data on state of health of the battery system 456. The battery system 456 may also include a battery controller 462, which is configured to transmit instructions from the device controller 452 to the battery system 456 and information from the battery system 456 to the device controller 452.

### Examples of a Battery System State Space Prediction Model

FIG. 5A illustrates a conceptual diagram of a prediction framework for a battery system in an inference phase. FIG. 5A shows battery information during the past time period 506 and future time period 508. The battery information is divided into the control data 502 and the response data 504.

According to various embodiments, the control data 502 includes information pertaining to a control protocol governing a battery system and/or a device in which the battery system is situated. For instance, the control protocol may include data on current profile and/or power profile values measuring a charge/discharge rate of a battery system during one or more periods of time. Thus, the actual control protocol information 510 corresponds to control protocol data for actual control protocols applied to a battery system during one or more periods of time in the past. Similarly, the planned control protocol information 512 corresponds to a control protocol that is planned for the future and for which a prediction as to the resulting battery value is desired.

According to various embodiments, a control profile may include various types of parameters for a battery system, a device in which the battery system is situated, and/or the environment in which the device and battery system are located. For example, the input parameters may include one or more instructions to be provided to a battery system, such as a discharge rate. As another example, the input parameters may include one or more characteristics or instructions defining a task to be performed by the device. For instance, the input parameters may identify a distance to be traveled, a speed to be traveled, a weight associated with a payload to be carried, or any other parameters characterizing instructions to be provided to the device. As yet another example, the input parameters may include one or more state values associated with a device and/or battery system. For instance, the input parameters may include an existing “state of health” for a battery system, an ambient temperature, an existing level of charge of the battery system, a distance previously traveled by a vehicle, a time elapsed since last service of a vehicle, or any other measurable values.

According to various embodiments, the response data 504 corresponds to an observed value of the battery system that occurs at least partially in response to the control protocol at that point in time, and potentially also in response to historical data forthe battery system as well. Thus, the observed battery value data 514 corresponds to battery value information that was observed in the past and that corresponds to the actual control protocol information 510 in timing. The predicted battery value data 516 corresponds to desired information about the state of the battery system in the future in response to the planned control protocol 512.

FIG. 5B illustrates a conceptual diagram of a prediction framework for a battery system in a training phase. Because FIG. 5B corresponds to a training phase in which outcome data is available, all of the information reflected in FIG. 5B is necessarily from the past. However, the training data may be observed or simulated. Thus, FIG. 5B shows battery information during an earlier past time period 556 and a later past time period 558. The battery information is again divided into the control data 552 and the response data 554.

According to various embodiments, the control data 552 includes information pertaining to a control protocol provided to a battery system, as with the control data 552. Thus, the actual control protocol data 560 and 562 correspond to control protocols applied in different periods in the past.

According to various embodiments, the response data 554 corresponds to an observed value of the battery system that occurs at least partially in response to the control protocol at that point in time, and potentially also in response to historical data forthe battery system as well. Thus, the observed battery value data 564 corresponds to battery value information that was observed in the past and that corresponds to the actual control protocol information 560 in timing. The blanked battery value data 566 also corresponds to battery value information that was observed in the past but that instead corresponds to the actual control protocol information 562 in timing.

In some embodiments, for the purpose of model training, the blanked battery value data 566 may be selectively blanked. Then, the model may be applied to try to predict the blanked battery value data 566. The actual values of the blanked battery value data 566 may then be used to update the weights of the model, for instance in a back propagation phase. This process may be repeated to train the model to predict the battery value.

FIG. 6 illustrates a diagram of a battery value temporal convolutional neural network 600, configured in accordance with one or more embodiments. The battery value temporal convolutional neural network 600 is one example of a possible configuration of a battery system state space prediction model 420.

The battery value temporal convolutional neural network 600 includes a number of neurons in communication with one another. According to various embodiments, the battery value temporal convolutional neural network 600 is configured to predict battery values at a future time t based on observed battery value information, past control protocol information, and future control protocol information.

In some embodiments, the battery value temporal convolutional neural network 600 may be implemented at a battery system. For instance, the battery value temporal convolutional neural network 600 may be implemented at a battery management system controller.

In some embodiments, the battery value temporal convolutional neural network 600 may be implemented at a remote computing system. For instance, the battery value temporal convolutional neural network 600 may be implemented in a cloud computing environment, a fleet management server, or any other suitable computing system in communication with a battery system via a network or communication bus.

The neurons in the battery value temporal convolutional neural network 600 are divided into layers, including a battery data input layer 602, a hidden layer 1 604, a hidden layer 2 606, and a battery value output layer 608. Although the diagram illustrated in FIG. 6 includes only two hidden layers for the purpose of illustration, in practice a battery value temporal convolutional neural network may include various numbers of hidden layers. For instance, a battery value temporal convolutional neural network may include one, two, ten, or any suitable number of layers.

In some embodiments, a neuron in the battery value output layer 608 corresponds to one or more predicted values associated with a battery state at a point in time. For instance, the neuron 630 corresponds to a battery state at time t+2, while the neuron 634 corresponds to a battery state at time t+1, where t is the current point in time.

According to various embodiments, the predicted battery values associated with a neuron in the battery value output layer 608 may include any of a variety of information about a battery system. Such information may include, but is not limited to: battery response values, battery parameter values, and/or battery state values.

According to various embodiments, the state information may be determined for any suitable level of analysis of a battery system. For instance, the value information may be determined at the level of the battery system, the battery pack, or the battery node, depending on the availability of data.

According to various embodiments, a neuron in the battery data input layer may correspond to input data during a period of time. For instance, the neurons 612, 614, 616, and 618 correspond to input data at time t−1, t, t+1, and t+2, respectively.

According to various embodiments, the input data may include any or all of past control protocol information, future control protocol information, observed battery value information, and/or predicted battery value information. For example, to predict the one or more battery values 630 at time t+2, the input layer neurons 612 and 614 may encode observed battery value information and actual control protocol information at times t−1 and t, respectively. However, because the times t+1 and t+2 are in the future, the input layer neuron 616 may encode predicted battery value information and future (i.e., hypothetical) control protocol information for times t+1 and t+2, as discussed conceptually with respect to FIG. 6.

According to various embodiments, a neuron in the battery value temporal convolutional neural network 600 may include an activation function. For instance, the activation function may be a rectified linear unit (ReLU) activation function. However, any suitable activation function may be employed. The activation function may activate to send an output signal based on inputs to the neuron and one or more weights learned in a training phase.

In the battery value temporal convolutional neural network 600 shown in FIG. 6, each neuron past the battery data input layer 602 receives as input signals from two different input neurons. For example, the neuron 626 receives input signals from the neurons 616 and 618, while the neuron 622 receives input signals from the neurons 612 and 614. In practice, neurons in different battery value temporal convolutional neural networks may receive various numbers of input signals, depending on the configuration.

The configuration of the battery value temporal convolutional neural network 600 is such that a neuron in a hidden layer effectively dilates time by receiving as input signals generated by neurons corresponding to two or more periods of time but producing only a single output. For instance, the neuron 626, although positioned in the period t+2, encompasses input signals from both the periods t+1 and t+2. Similarly, the neuron 628, although also positioned in the period t+2, encompasses input signals from the periods t−1, t, t+1 and t+2. In this way, information from a potentially lengthy period of time may be collapsed into a small number of neurons. For instance, the neuron 630 reflects information from the period of time ranging from t−6 to t+2, by virtue of its input signals received from both the neuron 632 and the neuron 628.

In some embodiments, some neurons may not contribute to an output signal at a particular period of time. For instance, the dotted arrows illustrate signals that are not employed when predicting the battery state at time t+2 but that may be employed when predicting the battery state at a different point in time. As one example, when predicting the battery state at time t+2, the neuron 624 is not employed due to the nature of the time dilation. For time t+2, the neurons 614 and 616 send their input signals to the neurons 622 and 626 instead. However, the neuron 624 would be employed when predicting the battery state output layer neuron 634 at time t+1.

According to various embodiments, battery value temporal convolutional neural networks may have various numbers of neurons and layers. For example, the diagram illustrated in FIG. 6 includes only 32 neurons for the purpose of illustration. However, in practice, different battery value temporal convolutional neural networks may include different numbers (e.g., hundreds, thousands, or millions) of neurons. As another example, the diagram illustrated in FIG. 6 includes only 2 hidden layers for the purpose of illustration. However, in practice, different battery value temporal convolutional neural networks may include different numbers (e.g., one, two, ten, hundreds, or thousands) of hidden layers. Increasing the number of hidden layers may result in a neural network capable of taking into account more input data, since a number of neurons in a hidden layer can dilate two or more times that number of neurons in an earlier layer. However, increasing the number of hidden layers may also result in a neural network that requires more space to store and/or more time to train.

In particular embodiments, one or more characteristics of the battery value temporal convolutional neural network may be determined by hyperparameter tuning. Examples of characteristics that may be tuned as hyperparameters include, but are not limited to: the number of neurons, the number of hidden layers, the degree of time dilation, the number of inputs to a given neuron, and the types of information included in the battery data input layer 602.

### Training a Battery System State Space Prediction Model

FIG. 7 illustrates a method 700 for training a battery system state space prediction model, performed in accordance with one or more embodiments. According to various embodiments, the method 700 may be performed at any suitable computing device, such as one or more of the devices or components shown in FIG. 4.

A request to determine a battery system state space prediction model is received at 702. The request may be generated based on an automated process or may be generated based on user input. The request may identify one or more characteristics of a battery system and/or device including a battery system for training the network, characteristics which may be used to determine one or more configuration parameters and/or training datasets.

An initialized battery system state space prediction model is determined at 704. In some embodiments, the initialized battery system state space prediction model may be a neural network that has not yet been trained but that has been configured based on one or more configuration parameters. Examples of such configuration parameters may include, but are not limited to: a number of neurons, a number of hidden layers, a degree of time dilation, initial weights, neuron activation functions, types of input data, types of values predicted by the network, and/or any other parameters.

In some embodiments, the initialized battery system state space prediction model may be a random forest model that has not yet been trained but that has been configured based on one or more configuration parameters. Examples of such configuration parameters may include, but are not limited to, initial and/or potential values for tree depth, number of trees, and features to be included in the random forest model.

In some embodiments, the initialized battery system state space prediction model may be a multilayer perceptron network that has not yet been trained but that has been configured based on one or more configuration parameters. Examples of such configuration parameters may include, but are not limited to, features to include in the model as well as initial and/or potential values for the number of neurons, activation function, optimizer, learning rate, batch size, and epochs.

In some embodiments, the initialized battery system state space prediction model may be a trained battery system state space prediction model that was previously trained and is being updated in the method 700 shown in FIG. 7. For example, a battery system state space prediction model may be initially trained using a pre-training dataset and then be updated with application data as such data becomes available. As another example, an existing battery system state space prediction model may be updated based on newly received data from a field environment.

According to various embodiments, one or more configuration parameters may be determined based on user input. Alternatively, or additionally, one or more configuration parameters may be selected based on characteristics of the battery system.

In particular embodiments, one or more configuration parameters may be determined based on hyperparameter tuning. For instance, different battery value temporal convolutional neural networks may be trained using different combinations of hyperparameters, with the trained battery system state space prediction model selected that performs best according to one or more performance metrics.

A training dataset for model training is identified at 706. According to various embodiments, the training dataset may include values for any observable characteristics of the battery system and/or device in which the battery system is situated. Values for observable characteristics that are controllable or environmental may be designated as input parameters, while battery state values (e.g., battery health) may be designated as output values predicted by the model.

In some embodiments, a training dataset may include data observed in a laboratory environment. Alternatively, or additionally, a training dataset may include data observed in a field environment, for instance transmitted from a controller associated with a device or battery system. As still another possibility, a training dataset may include data generated based on a physics model.

One or more future-blanked observations are determined at 708. According to various embodiments, a future-blanked observation may be any observation in the timeseries dataset where a value capable of being predicted by the model, such as a battery state value, is masked or blanked. The masked or blanked value may be reserved so that when it is predicted by the model, the predicted value may be compared with the actual value for the purpose of training.

According to various embodiments, an observation to future-blank may be selected in any suitable order, in sequence or in parallel. For example, a set of observations may be future-blanked and used to train the model in temporal sequence. As another example, observations may be selected at random for future-blanking and training from a training dataset. As discussed in more detail below, observations may also be selected for past-blanking.

At 710, one or more intermittent-blanked observations are optionally determined. In many real-world applications, the data available for predicting a value of a battery system includes one or more missing values due to factors such as sensor faults and the like. Accordingly, in some embodiments, one or more values normally used by the battery system state space prediction model to predict a battery value may be artificially blanked to simulate such a situation. Intermittently blanking one or more data values in such a way may lead to the construction of a battery system state space prediction model that is more robust to missing data than would otherwise be the case. Observations may be selected for intermittent-blanking at random or according to any suitable selection criteria.

A battery state in a future-blanked observation is selected by applying the battery system state space prediction model to the dataset after future-blanking and optional intermittent-blanking. Additional details regarding the application of the battery system state space prediction model to training data to produce a prediction are discussed throughout the application as filed.

A loss value is determined at 714 by comparing the predicted battery state to the future-blanked value. According to various embodiments, any of a variety of loss functions may be used. For instance, the loss function may impose a loss value penalizing the square of the loss.

One or more model parameters are updated at 716. According to various embodiments, the specific techniques employed for updating the model parameters may vary based at least in part on the type of model being trained. For example, in a neural network, neuron weights may be updated using a backpropagation and gradient descent. However, in other types of models, a different updating technique may be used.

A determination is made at 718 as to whether to perform an additional training iteration. According to various embodiments, training may continue until one or more criteria are satisfied. For example, training may continue until successive training iterations yield a limited improvement in model performance. As another example, training may continue until all or a designation proportion of the available training data has been analyzed. As yet another example, training may continue until a designated number of training iterations have been performed.

The trained or pre-trained battery system state space prediction model is stored at 720. The trained or pre-trained model may then be used for predicting battery states, as discussed throughout the application.

According to various embodiments, a training process for training a battery system state space prediction model may include one or more operations not shown in FIG. 7. For example, k-fold validation may be used to avoid overfitting the model. As another example, training may be divided into epochs, for instance to train the model using data having different time scales.

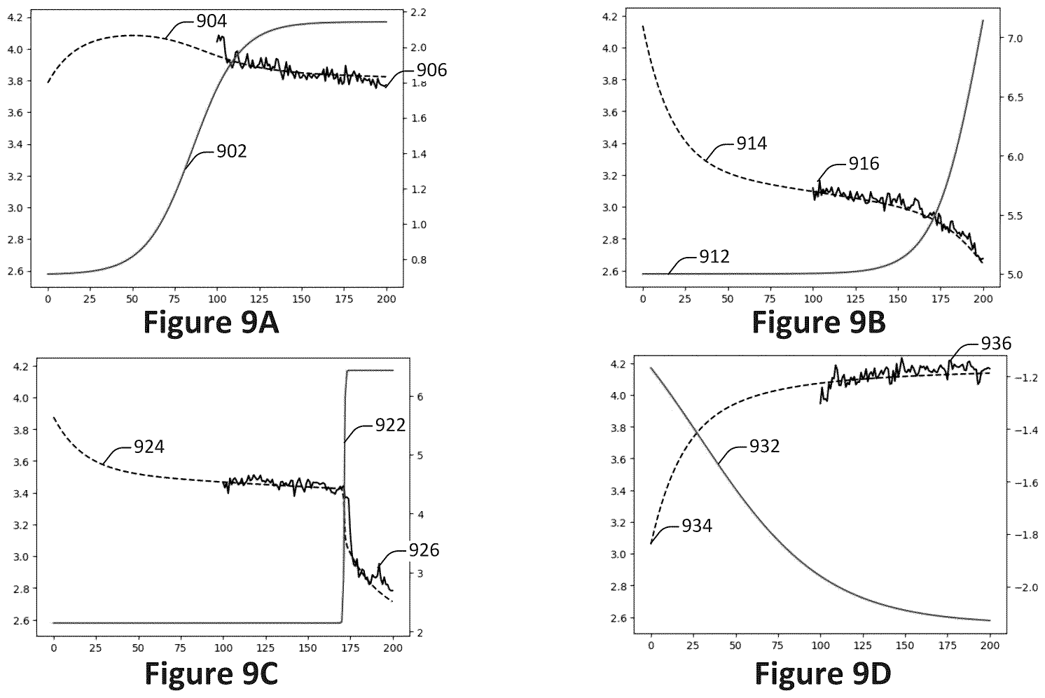

FIG. 8A, FIG. 8B, FIG. 8C, and FIG. 8D illustrate examples of plots generated in accordance with one or more embodiments. In FIG. 8A, FIG. 8B, FIG. 8C, and FIG. 8D, the lines 802, 812, 822, and 832 correspond to different control protocols that may be employed. Each control protocol is specified as a current protocol and/or power protocol over time and is represented on the right-side y-axis. The control protocols 802, 812, 822, and 832 were generated using a sigmoid basis. However, as discussed herein, various approaches may be used to generate a control protocol.

In FIG. 8A, FIG. 8B, FIG. 8C, and FIG. 8D, the lines 804, 814, 824, and 834 correspond to battery state values—in this case, voltage—predicted by one or more physics models. However, as discussed herein, various predicted battery state values may be determined, not only voltage values.

For example, FIG. 9A, FIG. 9B, FIG. 9C, and FIG. 9D illustrate examples of plots generated in accordance with one or more embodiments. In FIG. 9A, FIG. 9B, and FIG. 9C, the same control protocol is shown at 902, while different types of outcome values are predicted. For instance, the dotted line 904 corresponds to voltage, the dotted line 906 corresponds to open-circuit voltage, and the dotted line 908 corresponds to internal resistance. In FIG. 9D, the line 910 shows internal resistance on the y-axis as predicted by the physics model as a function of predicted open-current voltage on the x-axis.

For the purpose of exposition, the plots shown in FIG. 8A, FIG. 8B, FIG. 8C, FIG. 8D, FIG. 9A, FIG. 9B, FIG. 9C, and FIG. 9D are stylized examples in which a control protocol includes a single timeseries input over time which is used to predict a single battery state over time. According to various embodiments, however, techniques and mechanisms described herein may differ from these stylized examples in any of various ways. For example, a control protocol may include various numbers and types of input parameters. As another example, a predicted state of the battery system may include values such as state of health, remaining useful life, and the like. As yet another example, a battery state prediction model need not necessarily be trained to make inferences based on time series data. For instance, in the case of a cross-sectional prediction model such as a random forest model or multilayer perceptron model, a battery state prediction model may receive as an inference observation a control protocol parameterized as cross-sectional data and may predict a battery state at a point in time after the execution of the control protocol.

### Applying a Battery System State Space Prediction Model

FIG. 10 illustrates a method 1000 of controlling a device, performed in accordance with one or more embodiments. The method 1000 may be performed in order to control any type of device that includes a battery system and for which a battery system state space prediction model has been trained. For example, the method 1000 may be performed to control an electric vehicle (e.g., an automobile or airplane), an autonomous or remotely controlled device (e.g., a drone or a robot), or a power delivery system.

A request to perform an action at a device is received at 1002. In some implementations, all or a portion of the method 1000 may be performed at the device being controlled. For instance, the method 1000 may be performed at a device controller. Alternatively, or additionally, all or a portion of the method 1000 may be performed at a computing system that is located remotely from the device being controlled. For instance, one or more operations may be performed in a cloud computing environment in communication with the device via a network.

A trained battery system state space prediction model is identified at 1004. In some embodiments, battery system state space prediction model may be trained as discussed with respect to the method 700 shown in FIG. 7. The trained battery system state space prediction model may be retrieved from a storage device, received via a network interface, or identified in any other suitable way.

According to various embodiments, the trained battery system state space prediction model may receive as inputs one or more parameters, which may include any of a variety of types of information. For example, the input parameters may include one or more instructions to be provided to a battery system, such as a discharge rate. As another example, the input parameters may include one or more characteristics or instructions defining a task to be performed by the device. For instance, the input parameters may identify a distance to be traveled, a speed to be traveled, a weight associated with a payload to be carried, or any other parameters characterizing instructions to be provided to the device. As yet another example, the input parameters may include one or more state values associated with a device and/or battery system. For instance, the input parameters may include an existing “state of health” for a battery system, an ambient temperature, an existing level of charge of the battery system, a distance previously traveled by a vehicle, a time elapsed since last service of a vehicle, or any other measurable values.

One or more fixed parameters for performing the action at the device are identified at 1006. In some implementations, the fixed parameters may include any values that may not be changed if the device is to accomplish the requested action.

For example, the fixed parameters may include observed characteristics about the battery system, the device in which the battery system is situated, and/or the environment in which the device is situated. Observed characteristics about the battery system may include, for instance, a present state of health for the battery system and/or a present state of charge for the battery system. Fixed parameters for the device itself may include, for instance, a time elapsed since previous service, a maintenance level, a capability level, and/or any other fixed or changing device characteristics. Fixed parameters for the environment may include, for instance, ambient temperature, windspeed, traffic patterns, geographic location, and/or any other fixed or changing characteristics about the ambient environment.

As another example, consider a situation in which an electric vehicle is tasked with delivering an object of fixed weight from a source to a destination. In this example, the object's weight, the location of the source, and the location of the destination may all be treated as fixed parameters, while the path traveled between the source and destination, the speed traveled, the time at which the traveling occurs, and other such values may be treated as variable parameters.

As yet another example, consider a situation in which a number of items need to be moved from a source to a destination in one or more trips by a number of electric vehicles. In this example, the source and the destination may be fixed, but the weight of the items to be moved may be treated as a variable parameter since the items may be divided out differently across the trips and vehicles.

According to various embodiments, the fixed parameters may include any of various types of information. For example, the input battery system value data may include information collected from one or more sensors at the device. Such information may include characteristics such as temperature and current associated with a battery system. As another example, the input battery system value data may include historical information associated with the battery system and determined during previous time intervals. Such information may be retrieved from a storage device or a memory module where it was stored for later use. As yet another example, the fixed parameters may include any information regarding the present or past performance, control, and/or characteristics of the battery system or device.

In some embodiments, the fixed parameters may be included in the request. Alternatively, or additionally, one or more fixed parameters may be identified in some other manner, for instance based on user input.

One or more candidate variable parameter values for performing the action at the device are identified at 1008. In some embodiments, the candidate variable parameter values may correspond to input parameters for the trained battery system state space prediction model but may correspond to elements that could be changed while still performing the requested action. For example, in the electric vehicle context, parameters such as the route between a source and a destination, a speed at which a route is traveled, an amount of idle time, an amount of cargo weight being carried, an aircraft taxi time, a takeoff and/or landing speed for an aircraft, and the like may be varied while still performing an action to move from a source to a destination.

According to various embodiments, one or more candidate variable parameter values may be identified based on user input, may be included in the request received at 1002, or may be identified in some other way. For example, the request received at 1002 may identify a range of potential values for a parameter. The system may then select values from within the range and test control profiles with various values in a manner similar to hyperparameter tuning in machine learning.

A candidate control profile is identified at 1010 based on the one or more fixed parameter values and the one or more candidate variable parameter values. In some embodiments, the candidate control profile may be defined as the set of all parameters provided to the battery system state space prediction model as inputs. Determining the candidate control profile may involve transforming one or more of the parameter values, for instance by converting time-series values to cross-sectional values to match the parameterization of the battery system state space prediction model. For example, a set of time-series observations may be converted to one or more events that effectively discretize the data.

Predicted battery system state space value data is determined for the device at 1012 by applying the trained battery system state space prediction model to the candidate control profile. In some embodiments, the predicted battery system state space value may include a value indicative of an absolute value and/or a change in value of a parameter representing the long-term health and/or remaining useful life of a battery system. For instance, the predicted battery system state space value may indicate an estimated number of remaining charge cycles, number of days of remaining useful life, amount of time needed before system servicing, or other such indicators of battery system health.

A determination is made at 1014 as to whether to identify an additional candidate protocol for analysis. In some embodiments, the determination may be made based at least in part by evaluating the predicted battery system state space value data. For instance, additional candidate control protocols may not be needed if a predicted battery system state space value meets a designated threshold.

In some embodiments, the determination may be made based at least in part on whether a designated number of candidate control profiles may be tested. For instance, all candidate control profiles in a set of candidate control profiles (e.g., with different combinations of parameter values) may be tested.

A control protocol for performing the action is selected at 1016 based on the predicted battery system state value data. In some embodiments, the control protocol may be selected at least in part based on one or more predetermined criteria. For example, the system may select the control protocol that performs the requested action while having the least negative impact on battery system health. As another example, the system may select the control protocol that performs the requested action while having the least negative impact on battery system health while at the same time meeting one or more other criteria, such as transit speed. As yet another example, the system may select the control protocol based on an objective function that combines battery system health with one or more other elements, such as speed.

In some embodiments, the control protocol may be selected at least in part based on user input. For example, an operator may review information associated with one or more of the control protocols and associated predicted battery system state space value data and then make a decision as to which control protocol to employ. For instance, an operator may decide to take a faster route at the cost of an increased impact on the battery system's long-term state of health, or may instead decide to take a slower route to reduce the impact on the battery system's long-term state of health.

In particular embodiments, the predicted battery system state space value data may be associated with pricing information. For instance, battery power may be sold as a service, with the battery system operating in communication with a remote computing system that manages the service. In such a situation, battery usage may be priced in proportion to the reduction in battery system state of health. Accordingly, a device operator may choose, for instance, to select a course of action and control profile associated with a relatively higher impact on the battery system's long-term state of health and hence with a higher price, or instead to select a course of action and control profile associated with a relatively lower impact on the battery system's long-term state of health and hence with a lower price.

An instruction is transmitted to the device controller at 1018. According to various embodiments, the instruction may include any communication needed to implement the selected control protocol. For instance, the instruction transmitted may depend on the nature of the device controller and the control protocol selected at 1016.

FIG. 11 illustrates a method 1100 of controlling a fleet of devices, performed in accordance with one or more embodiments. One or more of the devices may include a battery system. The fleet of devices may be controlled by selecting a device and a control profile for the battery system and then identifying a course of action corresponding to the selected control profile. The control profile and the device may be selected based at least in part on a battery value predicted by a battery value temporal convolutional neural network.

According to various embodiments, the method 1100 may be employed for various types of devices. Examples of such devices may include, but are not limited to: autonomous robots, user-controlled robots, autonomous vehicles, user-controlled vehicles, or any other type of device having a battery system.

In some embodiments, the method 1100 may be performed at least in part at a remote computing system. For instance, a remote computing system may communicate with the fleet of devices via a network. The remote computing system may then select a device and a control profile for the device based on information associated with the device and then transmit an indication of the control profile and/or course of action corresponding to the control profile to the selected device.

A request to perform an action is received at 1102. In some embodiments, the request may include information capable of being used to identify a battery load needed to perform the requested action. For example, the request may identify one or more vehicle or robot destinations, operations, loads, or other such information.

One or more candidate devices potentially able to perform the action are identified at 1104. The devices may be identified by a fleet management system tasked with managing the devices. In some embodiments, all available devices may be identified. Alternatively, a subset of the devices meeting one or more criteria may be identified. For example, the identified devices may include those in the vicinity of an area in which the requested action is to be performed. As another example, the identified devices may include those having a designated amount of charge remaining in a battery system. Various criteria are possible, and may be strategically determined based on the characteristics of the devices and the requested action.

One or more candidate control protocols for performing the action are determined at 1106. According to various embodiments, techniques for determining the candidate control protocols may depend in significant part on the particular application in which the predicted battery system value data is determined. For example, in the robotics context, different candidate control protocols may correspond to different candidate sequences of actions to be performed by a robot to accomplish a goal. As another example, in the vehicle context, different candidate control protocols may correspond to different routes that may be traveled to reach one or more destinations.

In some embodiments, multiple devices may have the same candidate control protocols. For instance, a fleet of devices may include two or more similar devices located in approximately the same place. Alternatively, or additionally, different devices may have different control protocols. For instance, a fleet may include devices that differ in characteristics such as location, condition, battery systems, capabilities, and/or other such attributes. In such a situation, different devices may need different sequences of operations to perform a requested action and hence be associated with different control protocols.

A trained battery system state space prediction model is identified at 1108. According to various embodiments, the battery system state space prediction model may have been trained as discussed with respect to the method 700 shown in FIG. 7. The battery system state space prediction model need not have been trained using the specific battery system included in the device and the specific device in which the battery system is included, but rather need only have been trained to predict battery values for the type battery system and/or the type of device.

In some embodiments, multiple trained battery system state space prediction networks may be identified. For instance, different devices in the fleet may be equipped with different battery systems corresponding with different battery system state space prediction networks.

A device is selected at 1110. A candidate control protocol is determined at 1112. Predicted battery system state space value data for the selected device is determined at 1116. According to various embodiments, devices and candidate control protocols may be analyzed in any suitable order, in sequence or in parallel. A candidate control profile and predicted battery system state space value data may be determined as discussed with respect to the method 1000 shown in FIG. 10.

At 1116, a determination is made as to whether to select an additional control protocol for analysis. At 1118, a determination is made as to whether to select an additional device for analysis. In some embodiments, additional control protocols and devices may continue to be selected until all identified control protocols have been analyzed. Alternatively, or additionally, another type of terminating condition may be employed. For instance, additional control protocols and devices may continue to be selected until a device and associated control protocol meeting one or more selection criteria are identified.

A device and control protocol for performing the action are selected at 1120 based at least in part on the predicted battery system value data. According to various embodiments, the criteria employed for selecting the device and control protocol may depend in significant part on the particular application, and thus may be strategically determined based on any of a variety of considerations.

In some embodiments, selecting the device and control protocol may involve determining which device and control protocol analyzed as discussed with respect to operations 1110 through 1118 are associated with the best predicted battery system state. For instance, the control protocol that causes the least reduction in remaining useful life may be selected.

In some embodiments, the device and control protocol may be selected based on more than one criteria. For instance, the device and control protocol may be selected that is associated with the course of action having the shortest path, subject to a constraint such that the change in state associated with a battery system fall below a designated threshold.

In some embodiments, the device and control protocol may be selected to ensure that the selected device does not drop below a minimum state of charge at any time during the execution of the control protocol.

An instruction is transmitted to the selected device at 1122. In some embodiments, the instruction may identify the control protocol. Alternatively, or additionally, the instruction may identify a course of action corresponding with the selected control protocol.

According to various embodiments, the method 1100 may be employed in a matching context, to determine a set of devices and control protocols predicted to be able to collectively perform a requested set of tasks.

### CONCLUSION

In the foregoing specification, various techniques and mechanisms may have been described in singular form for clarity. However, it should be noted that some embodiments include multiple iterations of a technique or multiple instantiations of a mechanism unless otherwise noted. For example, a system uses a processor in a variety of contexts but can use multiple processors while remaining within the scope of the present disclosure unless otherwise noted. Similarly, various techniques and mechanisms may have been described as including a connection between two entities. However, a connection does not necessarily mean a direct, unimpeded connection, as a variety of other entities (e.g., bridges, controllers, gateways, etc.) may reside between the two entities.

In the foregoing specification, reference was made in detail to specific embodiments including one or more of the best modes contemplated by the inventors. While various implementations have been described herein, it should be understood that they have been presented by way of example only, and not limitation. For example, some techniques and mechanisms are described herein in the context of particular configurations of battery packs. However, the techniques of the present invention apply to a wide variety of battery systems. Particular embodiments may be implemented without some or all of the specific details described herein. In other instances, well known process operations have not been described in detail in order not to unnecessarily obscure the present invention. Accordingly, the breadth and scope of the present application should not be limited by any of the implementations described herein, but should be defined only in accordance with the claims and their equivalents.

1. A method comprising:
receiving via a communication interface a request to determine a control profile for a device to perform a course of action, the request including a first one or more input values characterizing a state of a battery system included in the device, the request including a second one or more input values characterizing the course of action;
determining one or more fixed parameter values based on the first one or more input values and/or the second one or more input values;
determining a plurality of prospective control profiles for the device via a processor, the plurality of prospective control profiles sharing the one or more fixed parameter values, the plurality of prospective control profiles each having a respective set of variable parameter values that vary across the plurality of prospective control profiles;
applying a battery system state space prediction model to the plurality of prospective control profiles via a processor to determine a plurality of corresponding battery system state space output values;
determining a selected prospective control profile from the plurality of prospective control profiles based at least in part on the plurality of prospective control profiles; and
transmitting an instruction to a device controller to execute the selected prospective control profile.

2. The method recited in claim 1, wherein the device is an electric vehicle powered by the battery system, wherein the course of action includes moving from a source location to a destination location.

3. The method recited in claim 2, wherein the one or more fixed parameter values identify the source location and the destination location.

4. The method recited in claim 2, wherein the variable parameter values identify different speeds at which the electric vehicle may travel.

5. The method recited in claim 2, wherein the variable parameter values identify cargo amounts transported by the electric vehicle.

6. The method recited in claim 1, wherein the one or more fixed parameter values identify a state of health for the battery system prior to performing the course of action.

7. The method recited in claim 6, wherein the plurality of corresponding battery system state space output values identify a plurality of predicted changes in the state of health for the battery system after performing the course of action in accordance with the plurality of prospective control profiles.

8. The method recited in claim 1, wherein the plurality of corresponding battery system state space output values identify a plurality of predicted states of health for the battery system after performing the course of action in accordance with the plurality of prospective control profiles.

9. The method recited in claim 1, wherein the communication interface is located at a cloud computing system, and wherein the plurality of prospective control profiles correspond to different pricing levels for use of the battery system.

10. The method recited in claim 1, wherein a designated prospective control profile of the plurality of prospective control profiles includes a designated current profile defining an amount of current over a designated period of time or a designated power profile defining an amount of power.

11. The method recited in claim 1, wherein the first one or more input values encode information corresponding to one or more sensors associated with the battery system.

12. The method recited in claim 1, wherein the battery system state space prediction model is a temporal convolutional neural network.

13. The method recited in claim 1, wherein the battery system state space prediction model is a random forest model or a multilayer perceptron model.

14. The method recited in claim 1, wherein the plurality of corresponding battery system state space output values include a hidden value not observable via one or more sensors associated with the battery system, the hidden value selected from the group consisting of: a hidden resistance value, a hidden capacitance value, a hidden electrolyte connectivity value, and a hidden a cathode conductivity value.

15. One or more non-transitory computer readable media having instructions stored thereon for performing a method, the method comprising:
receiving via a communication interface a request to determine a control profile for a device to perform a course of action, the request including a first one or more input values characterizing a state of a battery system included in the device, the request including a second one or more input values characterizing the course of action;
determining one or more fixed parameter values based on the first one or more input values and/or the second one or more input values;
determining a plurality of prospective control profiles for the device via a processor, the plurality of prospective control profiles sharing the one or more fixed parameter values, the plurality of prospective control profiles each having a respective set of variable parameter values that vary across the plurality of prospective control profiles;
applying a battery system state space prediction model to the plurality of prospective control profiles via a processor to determine a plurality of corresponding battery system state space output values;
determining a selected prospective control profile from the plurality of prospective control profiles based at least in part on the plurality of prospective control profiles; and
transmitting an instruction to a device controller to execute the selected prospective control profile.

16. The one or more non-transitory computer readable media recited in claim 15, wherein the device is an electric vehicle powered by the battery system, wherein the course of action includes moving from a source location to a destination location.

17. The one or more non-transitory computer readable media recited in claim 16, wherein the one or more fixed parameter values identify the source location and the destination location.

18. The one or more non-transitory computer readable media recited in claim 16, wherein the variable parameter values identify different speeds at which the electric vehicle may travel.

19. A system comprising:
a communication interface configured to receive a request to determine a control profile for a device to perform a course of action, the request including a first one or more input values characterizing a state of a battery system included in the device, the request including a second one or more input values characterizing the course of action;
a storage device configured to store a battery system state space prediction model; and
one or more processors configured to:
determine one or more fixed parameter values based on the first one or more input values and/or the second one or more input values,
determine a plurality of prospective control profiles for the device via a processor, the plurality of prospective control profiles sharing the one or more fixed parameter values, the plurality of prospective control profiles each having a respective set of variable parameter values that vary across the plurality of prospective control profiles,
apply the battery system state space prediction model to the plurality of prospective control profiles via a processor to determine a plurality of corresponding battery system state space output values, and determine a selected prospective control profile from the plurality of prospective control profiles based at least in part on the plurality of prospective control profiles, and
transmitting an instruction to a device controller via the communication interface to execute the selected prospective control profile.

20. The system recited in claim 19, wherein the device is an electric vehicle powered by the battery system, wherein the course of action includes moving from a source location to a destination location, and wherein the one or more fixed parameter values identify the source location and the destination location.
